(19) United States
(12) Patent Application Publication
(10) Pub. No.: US 2009/0123667 A1
(43) Pub. Date: May 14, 2009

(54) Double-Sided Adhesive Tapes for Producing LC Displays Having Light-reflecting and Absorbing Properties

(75) Inventors: Marc Husemann, Hamburg (DE); Reinhard Storbeck, Hamburg (DE)

Correspondence Address: NORRIS, MCLAUGHLIN & MARCUS, PA, 875 THIRD AVENUE, 18TH FLOOR, NEW YORK, NY, 10022, US

(73) Assignee: TESA AB, Hamburg (DE)

(21) Appl. No.: 11/720,378

(22) PCT Filed: Dec. 2, 2005
(86) PCT No.: PCT/EP2005/056396

§ 371 Date: Jul. 10, 2007

(30) Foreign Application Priority Data
Dec. 2, 2004 (DE) 10 2004 058 279.3

(51) Int. Cl. C09J 7/00; C23C 14/34; B32B 38/00

(52) U.S. Cl. 428/1.5; 204/192.15; 156/230; 156/153; 216/67; 156/60

(57) ABSTRACT

The invention relates to an adhesive tape, especially for producing or gluing optical liquid crystal displays (LCDs). Said tape comprises a lower face and an upper face, the lower face having light-reflecting properties and the upper face having light-absorbing properties, a support film having an upper face and a lower face, said adhesive tape being provided on both sides with an adhesive layer. The inventive tape is characterized in that the support film has a content of antiblocking agents of less than 4000 ppm, the support film is brightly colored and at least one light-absorbing chromophoric layer is provided at least between the lower face of the support film and the adhesive layer disposed on said face.

The invention relates to double-sided pressure-sensitive adhesive tapes having multilayer carrier constructions and having light-reflecting and absorbing properties for producing liquid-crystal displays (LCDs).

Pressure-sensitive adhesive tapes in the age of industrialization are widespread processing auxiliaries. Particularly for use in the computer industry, very exacting requirements are imposed on pressure-sensitive adhesive tapes. As well as having a low outgassing behavior, the pressure-sensitive adhesive tapes ought to be suitable for use across a wide temperature range and ought to fulfill certain optical properties.

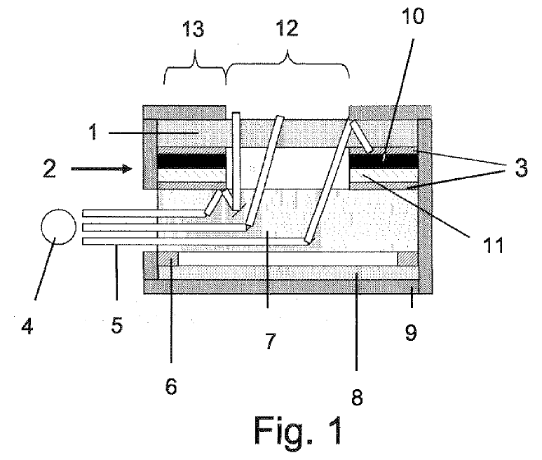

One field of use is that of LC displays, which are needed for computers, TVs, laptops, PDAs, cell phones, digital cameras, etc. One very widespread type of an LCD module for such applications is shown in FIG. 1.

FIG. 1 shows the approach for a double-sided adhesive tape having a black layer for absorption and a white layer for reflection, in accordance with the prior art; the key to the reference numerals is as follows:

| | |
|---|---|
| 1 | LCD glass |
| 2 | double-sided black-white adhesive tape |
| 3 | pressure-sensitive adhesive |
| 4 | light source (LED) |
| 5 | light beams |
| 6 | double-sided adhesive tape |
| 7 | optical waveguide |
| 8 | reflective film |
| 9 | LCD casing |
| 10 | black absorbing side of adhesive tape |
| 11 | white reflecting side |
| 12 | visible region |
| 13 | “blind” region |

For the production of LC displays, LEDs, as the light source, are bonded to the LCD glass. Frequently, black, double-sided pressure-sensitive adhesive tapes are used for this purpose. The aim of the black coloration is to prevent light penetrating from inside to outside and vice versa in the region of the double-sided pressure-sensitive adhesive tape. There are already numerous approaches in existence for achieving such black coloring.

On the other hand, there is a desire to increase the light efficiency of the back light module, and so it is preferred to use double-sided adhesive tapes which are black (light-absorbing) on one side and light-reflecting on the other side. For the production of the black side there are again numerous approaches in existence.

One approach to the production of black double-sided pressure-sensitive adhesive tapes lies in the coloration of the carrier material. Within the electronics industry great preference is attached to using double-sided pressure-sensitive adhesive tapes having polyester film carriers (primarily polyethylene terephthalate; PET), on account of their very good diecuttability. The PET carriers can likewise be colored with carbon black or other black pigments, in order to achieve light absorption. The disadvantage of this approach is the low level of light absorption. In very thin carrier layers it is possible to incorporate only a relatively small number of particles of carbon black or other black pigment, with the consequence that absorption of the light is incomplete. With the eye, and also with relatively intensive light sources (with a luminance of greater than 600 candelas) it is then possible to determine the deficient absorption.

Another approach to producing black double-sided pressure-sensitive adhesive tapes concerns the production of a two-layer carrier material by means of coextrusion. Carrier films are generally produced by extrusion. As a result of the coextrusion, as well as the conventional carrier material, a second, black layer is coextruded, fulfilling the function of light absorption. This approach too has a variety of disadvantages. For example, for extrusion it is necessary to use antiblocking agents, which then lead to what are called pinholes in the product. These pinholes are optical point defects (light passes through these holes) and adversely impact the functioning in the LCD.

By blocking is meant the unwanted characteristic of polymeric films and the like of sticking to one another above a certain temperature (blocking point) even under only gentle pressure. Blocking is countered using antiblocking agents (antiblockers, antiblocks).

Antiblocking agents are therefore substances which reduce or prevent the blocking of, for example, thermoplastic polymer films with themselves or with other materials as a result of cold flow or electrostatic charging.

For the production operation of, for example, PET films, antiblocking agents used are normally, for example, silicon dioxide (e.g., silica particles), siliceous chalk or other chalk, and zeolites.

Antiblocking agents are intended to prevent the baking-together of sheetlike polymeric films under pressure and temperature to form blocks. The antiblocking agent is typically worked into the thermoplastic mixture. The particles then function as spacers.

A further problem is posed by the layer thicknesses, since the two layers are first of all shaped individually in the die and it is therefore possible overall to realize only relatively thick carrier layers, with the result that the film becomes relatively thick and inflexible and hence its conformation to the surfaces to be bonded is poor. Moreover, the black layer must likewise be relatively thick, since otherwise it is not possible to realize complete absorption. A further disadvantage lies in the altered mechanical properties of the carrier material, since the mechanical properties of the black layer are different from those of the original carrier material (e.g., pure PET). A further disadvantage of the two-layer version of the carrier material is the difference in anchoring of the adhesive to the coextruded carrier material. In the case of such a version, there is always a weak point in the double-sided adhesive tape.

In a further approach, a black colored coating layer is coated onto the carrier material. This coating may take place single-sidedly or double-sidedly on the carrier. This approach too has a variety of disadvantages. On the one hand, here as well, defects (pinholes) are readily formed, and are introduced by antiblocking agents during the film extrusion operation. These pinholes are unacceptable for the final application in the LC display. Furthermore, the maximum absorption properties do not correspond to the requirements, since it is possible to apply only relatively thin coating films. Here as well, there is an upper limit on the layer thicknesses, since otherwise the mechanical properties of the carrier material would suffer alteration.

In the development of LC displays there is a trend developing. On the one hand, the LC displays are to become more lightweight and also flatter, and there is a rising demand for ever larger displays with ever higher resolution.

For this reason, the design of the displays has been changed and the light source, accordingly, is coming nearer and nearer to the LCD panel, with the consequence of an increased risk of more and more light penetrating from the outside into the marginal zone (“blind area”) of the LCD panel (see FIG. 1). With this development, therefore, there is also an increase in the requirements imposed on the shading properties (blackout properties) of the double-sided adhesive tape, and accordingly there is a need for new approaches to the production of black adhesive tapes.

Moreover, the double-sided adhesive tape is to be reflecting.

Known for this purpose are double-sided pressure-sensitive adhesive tapes which possess on one side a white or a metallic layer and a black light-absorbing layer. With these pressure-sensitive adhesive tapes, a distinct improvement has been obtained in respect of light reflection on one side and absorption on the opposite side, and yet, as a result of the antiblocking agents in the carrier layer, irregularities occur in the reflecting side.

Generally, double-sided pressure-sensitive adhesive (PSA) tapes having a white and a black layer have operational advantages over double-sided PSA tapes having a metallic and a black layer, since black-metallic PSA tapes or diecuts easily exhibit crease points (which in particular may also arise during the positioning in the LCD), which then have a direct negative effect on the reflection properties.

Some approaches to the production of light-absorbing and light-reflecting double-sided PSA tapes are proposed by patent specifications. To obtain a reflecting layer, then, it is possible in turn to provide the with PSA reflecting particles. The reflection properties obtainable, however, are relatively inadequate.

JP 2002-350612 describes double-sided adhesive tapes for LCD panels with light-protective properties. The function is achieved by means of a metal layer applied on one or both sides to the carrier film, it also being possible, additionally, for the carrier film to have been colored. The adhesive tapes described therein, however, have only this function, and thus do not combine the light-absorbing function on the one side and the light-reflecting function on the other side.

JP 2002-023663 likewise describes double-sided adhesive tapes for LCD panels that have light-protecting properties. Here again, the function is achieved by means of a metal layer applied on one or both sides to the carrier film.

DE 102 43 215 describes double-sided adhesive tapes for LC displays that have light-absorbing properties on the one side and light-reflecting properties on the other side. That patent describes black/silver double-sided PSA tapes.

For the adhesive bonding of LCD displays and for their production, therefore, there continues to be a need for double-sided PSA tapes which do not have the deficiencies described above, or which have them only to a reduced extent.

It is an object of the invention to provide a double-sided pressure-sensitive adhesive tape in which the effect of point defects (pinholes) in application is avoided or reduced, and which is capable of fully absorbing light and, on the opposite side, reflecting it.

Surprisingly it has been found that films containing antiblocking agent are suitable as carrier materials for producing certain double-sided pressure-sensitive adhesive tapes having light-absorbing and light-reflecting properties, of the kind set out hereinbelow, it being possible to improve this accessibility for this end use, unforeseeably for the skilled worker, by means of appropriate pretreatment, and the adhesive tapes obtained in this way unexpectedly have the desired advantages over the prior art. In particular, surprisingly, no adverse effect has been noted on the optical properties.

The invention relates accordingly to pressure-sensitive adhesive tapes, in particular those for the production of optical liquid-crystal displays (LCDs), having a top side and a bottom side, having light-reflecting properties on the top side and light-absorbing properties on the bottom side, comprising a carrier film having a top side and a bottom side, the pressure-sensitive adhesive tape being furnished on both sides with a pressure-sensitive adhesive layer, the carrier film having an antiblocking agent content of less than 4000 ppm, the carrier film being pale colored and there being at least one light-absorbing chromophoric layer at least between the bottom side of the carrier film and the pressure-sensitive adhesive layer located on that side.

Antiblocking agents in the sense of the invention may be, for example, in particular, silica particles, but also, for example, other silicon dioxides, siliceous chalk or other chalk, or zeolites.

The pressure-sensitive adhesive layers may be identical or else different.

The reduction or complete elimination of the antiblocking agents reduces or eliminates the number of potential pinhole defects. This is achieved in an improved way by means of an antiblocking agent fraction of <1000 ppm, preferably <500 ppm, and very preferably 0 ppm.

In one advantageous embodiment of the invention, the pale coloring of the carrier layer is achieved by the presence of white pigments.

The carrier film is preferably between 4 and 250 μm, more preferably between 8 and 50 μm, very preferably between 12 and 36 μm thick. It is pale colored, preferably white and of very low translucency.

Advantageously the carrier film used is roughened on at least one side. The preferred roughness in this case is preferably more than 50 nm and less than 400 nm, in particular less than 300 nm. The roughness can be determined by means for example of AFM (atomic force microscopy). The roughness data are therefore to be understood as RMS roughnesses. With further advantage in accordance with the invention, the film can be roughened on both sides, in which case either one or both sides may exhibit the abovementioned advantageous roughness values.

A metallically reflecting layer may be provided on the bottom side of the carrier film. This layer is preferably metallically lustrous and reduces the light absorption of the inventive PSA tape. The metallically reflecting layer is advantageously a metal coating. In one preferred version of the invention the carrier film carries vapor-deposited metal, aluminum or silver for example, on one side, the metal having been applied with particular advantage via the cathodic atomization coating process (sputtering). The thickness of the metallically reflecting layer is preferably between 5 nm and 200 nm. A second advantageous variant for producing the metallically reflecting layer is that of applying a silver-colored surface coating.

Between the bottom side of the carrier film and the pressure-sensitive adhesive layer located on that side is at least one light-absorbing chromophoric layer. The chromophoric layer is in particular a coating film which has a layer thickness, preferably, of between 0.01 and 5 μm.

As well as a first chromophoric layer there may be further chromophoric layers on both sides of the adhesive tape. In that case these are advantageously, again, coating films of the thickness indicated above.

In one very preferred version at least one of the chromophoric layers is black, in particular the outermost chromophoric layer. The chromophoric layers may differ in their chemical nature and may contain different chromophoric pigments, which have advantageous consequences for the light-absorbing properties.

The PSA layers preferably possess a thickness of in each case 5 μm to 250 μm. A further component of the invention is the choice of independent layer thicknesses for the individual layers within the double-sided PSA tape, and consequently it is possible, for example, to apply PSA layers differing in thickness.

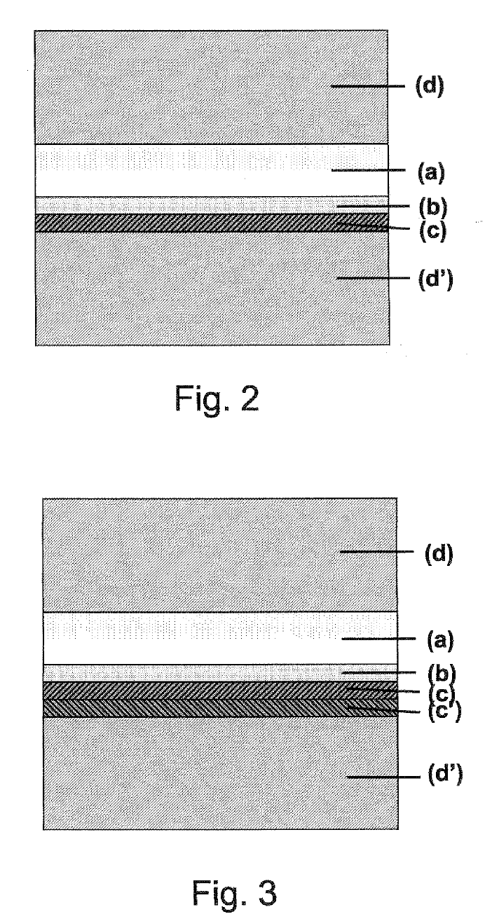

Below the intention is to highlight certain advantageous embodiments of the PSA tape of the invention (FIGS. 2 and 3), without wishing to impose any unnecessary restriction as a result of the choice of the examples illustrated.

The reference letters in the figures have the following meanings:

(a) carrier film layer
(b) metallically reflecting layer
(c) (first) chromophoric layer
(c′) further chromophoric layer
(d) PSA layer
(d′) PSA layer

In a first advantageous embodiment of the invention the carrier film is colored white and is provided with a metallically reflecting coating. A PSA tape of this kind is shown by way of example in FIG. 2. The inventive PSA tape is composed of a carrier film layer (a) containing a high white color pigment fraction and containing a reduced fraction, or none, of antiblocking agent, a metallically reflecting layer (b), a chromophoric layer (c) on the bottom side, and two PSA layers (d) and (d′), it being possible for the PSAs to be identical or to differ from one another.

In a second preferred embodiment of the invention the inventive PSA tape possesses the product construction shown in FIG. 3.

Here the double-sided PSA tape is composed of a carrier film (a), having a reduced fraction of antiblocking agent or none at all and a high white pigment fraction, a metallic layer (b) on the bottom side, at least two chromophoric layers coated one above the other, (c) and (c′) on the bottom side, and two PSA layers (d) and (d′) (one of each of the top and bottom sides), it being possible for the PSAs to be identical or to differ from one another.

The text below will give a more detailed description of the PSA tapes of the invention, there being no intention that the description should remain confined to the embodiments set out above by way of example.

As film carriers it is possible in principle to use all filmic polymer carriers which may be colored pale, in particular white. Thus it is possible, for example, to use polyethylene, polypropylene, polyimide, polyester, polyamide, polymethacrylate, fluorinated polymer films, etc. In one particularly preferred version, polyester films are used, more preferably PET (polyethylene terephthalate) films. The films may be in detensioned form or may have one or more preferential directions. Preferential directions are obtained by drawing in one or in two directions.

The films used for the inventive PSA tapes are films which contain only a very small fraction, if any, of antiblocking agent. An example of one such film is, for example, the Hostaphan™ 5000 series from Mitsubishi polyester film (PET 5211, PET 5333, PET 5210).

Particularly for the production of very thin PET films (for example, films 12 μm thick) it is very advantageous if the PET film is coated with metal and if the film contains no antiblocking agents or a significantly reduced fraction of antiblocking agents. Particularly good results have been obtained here in respect of the avoidance of pinholes. Furthermore, 12 μm PET films are particularly advantageous on account of the fact that they allow very good adhesive properties for the double-sided adhesive tape, since in this case the film is very flexible and is able to conform well to the surface roughnesses of the substrates that are to be bonded.

To improve the anchoring of the coating films or of the vapor-deposited metal it is very advantageous to pretreat the films. The films may be etched (e.g., trichloroacetic or trifluoroacetic acid), corona- or plasma-pretreated, or furnished with a primer (e.g., Saran).

Moreover, the film contains color pigments and/or chromophoric particles. In principle, the coloring pigments or particles customary to the skilled worker are suitable for coloring the film. Pigments having very high scattering capability are advantageously used. Advantageous examples for a white coloring are titanium dioxide pigments or particles or barium sulfate pigments or particles. The pigments or particles ought advantageously to be smaller in diameter than the ultimate layer thickness of the carrier film. Optimum colorations can be achieved with 5% to 40% by weight particle fractions, based on the film material.

The reflecting and hence also light-absorbing layer can be a metallic, and in particular a silver-colored, coating film on the film, and with advantage the reflecting layer can also be produced by means in particular of single-sided or double-sided vapor deposition coating of the film with a metal, e.g., aluminum or silver. The aluminum or silver is preferably applied very uniformly to the film. The use of the metallically reflecting layer has the twin effects of reflecting the incident light and of preventing or reducing the transmission of the light through the carrier material. In addition it is possible to compensate surface roughnesses of the carrier film.

The chromophoric layers may fulfill various functions. In one advantageous version of the invention the color layer possesses the function of complete absorption of external light. In this case the transmittance for the double-sided PSA tape within a wavelength range of 300-800 nm is <0.5%, more preferably <0.1%, very preferably <0.01%. In one preferred embodiment this is achieved with a black coating film as chromophoric layer. The layer is preferably composed of a coating-material matrix (cured binder matrix, preferably thermosetting system, but radiation-curing system also possible), with color pigments mixed into the coating-material matrix. Examples of coating materials which can be used include polyesters, polyurethanes, polyacrylates or polymethacrylates, in conjunction with the coatings additives that are known to the skilled worker. In one very preferred inventive embodiment the color pigments are black; as chromophoric particles it is preferred to mix carbon black or graphite particles into the binder matrix. At a very high level of additization (>20% by weight), this additization has the effect of producing not only complete light absorption but also, additionally, electrical conductivity, so that the inventive double-sided PSA tapes likewise possess antistatic properties.

To reinforce the absorbing characteristic of the black color layer, which is preferably the outer of the chromophoric layers, it is possible for a further chromophoric layer, preferably a chromophoric layer situated further toward the inside, to be provided with white color pigments as well. Suitable white color pigments are preferably titanium dioxide and/or barium sulfate pigments.

In one preferred embodiment the PSA layers are identical on both sides of the PSA tape of the invention. In one specific procedure, however, it may also be of advantage for the PSAs on the top and bottom sides of the PSA tape to differ from one another in respect of layer thickness and/or chemical composition. In this way it is possible, for example, to set different pressure-sensitive adhesion properties. PSA systems used for the inventive double-sided PSA tape are acrylate, natural-rubber, synthetic-rubber, silicone or EVA adhesives. Where the reflection on the top side of the PSA tape is to be very high, at least that side of the PSA tape ought preferably to have a high transparency.

As PSAs it is also possible in principle to use the further PSAs that are known to the skilled worker.

For natural rubber adhesives the natural rubber is milled to a molecular weight (weight average) of not below about 100 000 daltons, preferably not below 500 000 daltons, and additized.

In the case of rubber/synthetic rubber as starting material for the adhesive, there are wide possibilities for variation. Use may be made of natural rubbers or of synthetic rubbers, or of any desired blends of natural rubbers and/or synthetic rubbers, it being possible for the natural rubber or natural rubbers to be chosen in principle from all available grades, such as, for example, crepe, RSS, ADS, TSR or CV grades, in accordance with the purity level and viscosity level required, and for the synthetic rubber or synthetic rubbers to be chosen from the group of randomly copolymerized styrene-butadiene rubbers (SBR), butadiene rubbers (BR), synthetic polyisoprenes (IR), butyl rubbers (IIR), halogenated butyl rubbers (XIIR), acrylate rubbers (ACM), ethylene-vinyl acetate copolymers (EVA) and polyurethanes and/or blends thereof.

With further preference it is possible, in order to improve the processing properties of the rubbers, to add to them thermoplastic elastomers with a weight fraction of 10% to 50% by weight, based on the overall elastomer fraction. As representatives, mention may be made at this point, in particular, of the particularly compatible styrene-isoprene-styrene (SIS) and styrene-butadiene-styrene (SBS) types.

In one inventively preferred embodiment use is made of acrylate PSAs and/or of methacrylate PSAs.

(Meth)acrylate PSAs, which are obtainable by free-radical addition polymerization, consist to the extent of at least 50% by weight of at least one acrylic monomer from the group of the compounds of the following general formula:

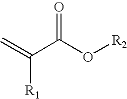

where R₁ is H or CH₃ and the radical R₂ is H or CH₃ or is selected from the group of branched or unbranched, saturated alkyl groups having 1-30 carbon atoms.

The monomers are preferably chosen such that the resulting polymers can be used, at room temperature or higher temperatures, as PSAs, particularly such that the resulting polymers possess pressure-sensitive adhesive properties.

In a further inventive embodiment the comonomer composition is chosen such that the PSAs can be used as heat-activable PSAs.

The polymers can be obtained preferably by polymerizing a monomer mixture which is composed of acrylic esters and/or methacrylic esters and/or the free acids thereof, with the formula CH₂═CH(R₁)(COOR₂), where R₁ is H or CH₃ and R₂ is an alkyl chain having 1-30 carbon atoms or is H.

The molar masses (weight average) M_{w} of the polyacrylates used amount preferably to M_{w}≧200 000 g/mol.

In one way which is greatly preferred, acrylic or methacrylic monomers are used which are composed of acrylic and methacrylic esters having alkyl groups comprising 4 to 14 carbon atoms, and preferably comprise 4 to 9 carbon atoms. Specific examples, without wishing to be restricted by this enumeration, are methyl acrylate, methyl methacrylate, ethyl acrylate, n-butyl acrylate, n-butyl methacrylate, n-pentyl acrylate, n-hexyl acrylate, n-heptyl acrylate, n-octyl acrylate, n-octyl methacrylate, n-nonyl acrylate, lauryl acrylate, stearyl acrylate, behenyl acrylate, and the branched isomers thereof, such as isobutyl acrylate, 2-ethylhexyl acrylate, 2-ethylhexyl methacrylate, isooctyl acrylate, and isooctyl methacrylate, for example.

Further classes of compound which can be used are monofunctional acrylates and/or methacrylates of bridged cycloalkyl alcohols consisting of at least 6 carbon atoms. The cycloalkyl alcohols can also be substituted, by C-1-6 alkyl groups, halogen atoms or cyano groups, for example. Specific examples are cyclohexyl methacrylates, isobornyl acrylate, isobornyl methacrylates, and 3,5-dimethyladamantyl acrylate.

In one procedure monomers are used which carry polar groups such as carboxyl radicals, sulfonic and phosphonic acid, hydroxyl radicals, lactam and lactone, N-substituted amide, N-substituted amine, carbamate, epoxy, thiol, alkoxy or cyano radicals, ethers or the like.

Moderate basic monomers are, for example, N,N-dialkyl-substituted amides, such as, for example, N,N-dimethylacrylamide, N,N-dimethylmethylmethacrylamide, N-tert-butylacryl-amide, N-vinylpyrrolidone, N-vinyllactam, dimethylaminoethyl methacrylate, dimethylaminoethyl acrylate, diethylaminoethyl methacrylate, diethylaminoethyl acrylate, N-methylolmethacrylamide, N-(buthoxymethyl)methacrylamide, N-methylolacrylamide, N-(ethoxymethyl)acrylamide, N-isopropylacrylamide, this enumeration not being exhaustive.

Further preferred examples are hydroxyethyl acrylate, hydroxypropyl acrylate, hydroxyethyl methacrylate, hydroxypropyl methacrylate, allyl alcohol, maleic anhydride, itaconic anhydride, itaconic acid, glyceridyl methacrylate, phenoxyethyl acrylate, phenoxyethyl methacrylate, 2-butoxyethyl methacrylate, 2-butoxyethyl acrylate, cyanoethyl methacrylate, cyanoethyl acrylate, glyceryl methacrylate, 6-hydroxyhexyl methacrylate, vinylacetic acid, tetrahydrofurfuryl acrylate, β-acryloyloxypropionic acid, trichloroacrylic acid, fumaric acid, crotonic acid, aconitic acid, and dimethylacrylic acid, this enumeration not being exhaustive.

In one further very preferred procedure use is made as monomers of vinyl esters, vinyl ethers, vinyl halides, vinylidene halides, and vinyl compounds having aromatic rings and heterocycles in α-position. Here again, mention may be made, nonexclusively, of some examples: vinyl acetate, vinylformamide, vinylpyridine, ethyl vinyl ether, vinyl chloride, vinylidene chloride, and acrylonitrile.

Moreover, in an advantageous procedure, use can be made of photoinitiators having a copolymerizable double bond. Suitable photoinitiators include Norrish I and II photoinitiators (Norrish type I reaction: photofragmentation (α cleavage) of the carbonyl compound into an acyl radical and an alkyl radical; Norrish type II reaction: intramolecular abstraction of a hydrogen atom positioned γ to the carbonyl group, induced by the photochemically excited carbonyl group, producing a diradical, which can break down into an enol and an alkene (β cleavage) or cyclizes to form a cyclobutanol). Examples include benzoin acrylate and an acrylated benzophenone from UCB (Ebecryl P 36®). In principle it is possible to copolymerize any photoinitiators which are known to the skilled worker and which are able to crosslink the polymer by way of a free-radical mechanism under UV irradiation.

In another preferred procedure the comonomers described are admixed with monomers which possess a high static glass transition temperature. Suitable components include aromatic vinyl compounds, an example being styrene, in which the aromatic nuclei consist preferably of C₄ to C₁₈ units and may also include heteroatoms. Particularly preferred examples are 4-vinylpyridine, N-vinylphthalimide, methylstyrene, 3,4-dimethoxystyrene, 4-vinylbenzoic acid, benzyl acrylate, benzyl methacrylate, phenyl acrylate, phenyl methacrylate, t-butylphenyl acrylate, t-butylphenyl methacrylate, 4-biphenylyl acrylate, 4-biphenylyl methacrylate, 2-naphthyl acrylate, 2-naphthyl methacrylate, and mixtures of these monomers, this enumeration not being exhaustive.

As a result of the increase in the aromatic fraction there is a rise in the refractive index of the PSA, and the scattering between LCD glass and PSA (as a result, for example, of extraneous light) is minimized.

For further development it is possible to admix resins to the PSAs. As tackifying resins for addition it is possible to use the tackifier resins known to the skilled worker. Representatives that may be mentioned include pinene resins, indene resins and rosins, their disproportionated, hydrogenated, polymerized, and esterified derivatives and salts, the aliphatic and aromatic hydrocarbon resins, terpene resins and terpene-phenolic resins, and also C₅, C₉, and other hydrocarbon resins. Any desired combinations of these and further resins may be used in order to adjust the properties of the resultant adhesive in accordance with requirements. Generally speaking it is possible to employ any resins which are compatible (soluble) with the polyacrylate in question: in particular, reference may be made to all aliphatic, aromatic and alkylaromatic hydrocarbon resins, hydrocarbon resins based on single monomers, hydrogenated hydrocarbon resins, functional hydrocarbon resins, and natural resins.

Here as well, the transparency is improved using, preferably, transparent resins which are highly compatible with the polymer. Hydrogenated or partly hydrogenated resins frequently feature these properties.

In addition it is possible optionally to add plasticizers, further fillers (such as, for example, fibers, carbon black, zinc oxide, chalk, solid or hollow glass beads, microbeads made of other materials, silica, silicates), nucleators, electrically conductive materials, such as, for example, conjugated polymers, doped conjugated polymers, metal pigments, metal particles, metal salts, graphite, etc., expandants, compounding agents and/or aging inhibitors, in the form of, for example, primary and secondary antioxidants or in the form of light stabilizers.

In another embodiment of the PSA tape of the invention the PSA on the bottom side of the PSA tape may likewise have been admixed with light-absorbing particles, such as black color pigments or carbon black particles or graphite particles, for example, as a filler.

In addition it is possible to admix crosslinkers and crosslinking promoters. Examples of suitable crosslinkers for electron beam crosslinking and UV crosslinking include difunctional or polyfunctional acrylates, difunctional or polyfunctional isocyanates (including those in block form), and difunctional or polyfunctional epoxides. In addition it is also possible for thermally activable crosslinkers to have been added, such as Lewis acid, metal chelates or polyfunctional isocyanates, for example.

For optional crosslinking with UV light it is possible to add UV-absorbing photoinitiators to the PSAs. Useful photoinitiators whose use is very effective are benzoin ethers, such as benzoin methyl ether and benzoin isopropyl ether, substituted acetophenones, such as 2,2-diethoxyacetophenone (available as Irgacure 651® from Ciba Geigy®), 2,2-dimethoxy-2-phenyl-1-phenylethanone, dimethoxyhydroxyacetophenone, substituted α-ketols, such as 2-methoxy-2-hydroxypropiophenone, aromatic sulfonyl chlorides, such as 2-naphthylsulfonyl chloride, and photoactive oximes, such as 1-phenyl-1,2-propanedione 2-(O-ethoxycarbonyl)oxime, for example.

The abovementioned photoinitiators and others which can be used, and also others of the Norrish I or Norrish II type, can contain the following radicals: benzophenone, acetophenone, benzil, benzoin, hydroxyalkylphenone, phenyl cyclohexyl ketone, anthraquinone, trimethylbenzoylphosphine oxide, methylthiophenylmorpholine ketone, aminoketone, azobenzoin, thioxanthone, hexaarylbisimidazole, triazine, or fluorenone, it being possible for each of these radicals to be additionally substituted by one or more halogen atoms and/or by one or more alkyloxy groups and/or by one or more amino groups or hydroxy groups.

The acrylate PSAs can be prepared as follows:

For the polymerization the monomers are chosen such that the resultant polymers can be used at room temperature or higher temperatures as PSAs.

In order to achieve a preferred polymer glass transition temperature T_{g} of ≦25° C. for PSAs it is very preferred, in accordance with the comments made above, to select the monomers in such a way, and choose the quantitative composition of the monomer mixture advantageously in such a way, as to result in the desired T_{g} for the polymer in accordance with the Fox equation (E1) (cf. T. G. Fox, Bull. Am. Phys. Soc. 1 (1956) 123).

$$\frac{1}{{T}_{g}} = {\sum }_{n}^{ } \frac{{w}_{n}}{{T}_{g , n}} \qquad ( E1 )$$

In this equation, n represents the serial number of the monomers used, w, the mass fraction of the respective monomer n (% by weight), and T_{g,n} the respective glass transition temperature of the homopolymer of the respective monomer n, in K.

For the preparation of the poly(meth)acrylate PSAs it is advantageous to carry out conventional free-radical polymerizations. For the polymerizations which proceed free-radically it is preferred to employ initiator systems which also contain further free-radical initiators for the polymerization, especially thermally decomposing, free-radical-forming azo or peroxo initiators. In principle, however, all customary initiators which are familiar to the skilled worker for acrylates are suitable. The production of C-centered radicals is described in Houben Weyl, Methoden der Organischen Chemie, Vol. E 19a, pp. 60-147. These methods are employed, preferentially, in analogy.

Examples of free-radical sources are peroxides, hydroperoxides, and azo compounds; some nonlimiting examples of typical free-radical initiators that may be mentioned here include potassium peroxodisulfate, dibenzoyl peroxide, cumene hydroperoxide, cyclohexanone peroxide, di-t-butyl peroxide, azodiisobutyronitrile, cyclohexylsulfonyl acetyl peroxide, diisopropyl percarbonate, t-butyl peroctoate, and benzpinacol. In one very preferred version the free-radical initiator used is 1,1′-azobis(cyclohexane-carbonitrile) (Vazo 88™ from DuPont) or azodiisobutyronitrile (AIBN).

The average molecular weights (weight average) M_{w} of the PSAs formed in the free-radical polymerization are very preferably chosen such that they are situated within a range of 200 000 to 4 000 000 g/mol; specifically for further use as electrically conductive hot-melt PSAs with resilience, PSAs are prepared which have average molecular weights M_{w} of 400 000 to 1 400 000 g/mol. The average molecular weight is determined by size exclusion chromatography (GPC) or matrix-assisted laser desorption/ionization mass spectrometry (MALDI-MS).

The polymerization may be conducted without solvent, in the presence of one or more organic solvents, in the presence of water, or in mixtures of organic solvents and water. The aim is to minimize the amount of solvent used. Suitable organic solvents are straight alkanes (e.g. hexane, heptane, octane, isooctane), aromatic hydrocarbons (e.g. benzene, toluene, xylene), esters (e.g. ethyl, propyl, butyl or hexyl acetate), halogenated hydrocarbons (e.g. chlorobenzene), alkanols (e.g. methanol, ethanol, ethylene glycol, ethylene glycol monomethyl ether), and ethers (e.g. diethyl ether, dibutyl ether) or mixtures thereof. A water-miscible or hydrophilic cosolvent may be added to the aqueous polymerization reactions in order to ensure that the reaction mixture is present in the form of a homogeneous phase during monomer conversion. Cosolvents which can be used with advantage for the present invention are chosen from the following group, consisting of aliphatic alcohols, glycols, ethers, glycol ethers, pyrrolidines, N-alkylpyrrolidinones, N-alkylpyrrolidones, polyethylene glycols, polypropylene glycols, amides, carboxylic acids and salts thereof, esters, organic sulfides, sulfoxides, sulfones, alcohol derivatives, hydroxy ether derivatives, amino alcohols, ketones and the like, and also derivatives and mixtures thereof.

The polymerization time—depending on conversion and temperature—is between 2 and 72 hours. The higher the reaction temperature which can be chosen, i.e., the higher the thermal stability of the reaction mixture, the shorter can be the chosen reaction time.

As regards initiation of the polymerization, the introduction of heat is essential for the thermally decomposing initiators. For these initiators the polymerization can be initiated by heating to from 50 to 160° C., depending on initiator type.

For the preparation it can also be of advantage to polymerize the (meth)acrylate PSAs without solvent. A particularly suitable technique for use in this case is the prepolymerization technique. Polymerization is initiated with UV light but taken only to a low conversion of about 10-30%. The resulting polymer syrup can then be welded, for example, into films (in the simplest case, ice cubes) and then polymerized through to a high conversion in water. These pellets can subsequently be used as acrylate hot-melt adhesives, it being particularly preferred to use, for the melting operation, film materials which are compatible with the polyacrylate. For this preparation method as well it is possible to add the thermally conductive materials before or after the polymerization.

Another advantageous preparation process for the poly(meth)acrylate PSAs is that of anionic polymerization. In this case the reaction medium used preferably comprises inert solvents, such as aliphatic and cycloaliphatic hydrocarbons, for example, or else aromatic hydrocarbons.

The living polymer is in this case generally represented by the structure P_{L}(A)-Me, where Me is a metal from group I, such as lithium, sodium or potassium, and P_{L}(A) is a growing polymer from the acrylate monomers. The molar mass of the polymer under preparation is controlled by the ratio of initiator concentration to monomer concentration. Examples of suitable polymerization initiators include n-propyllithium, n-butyllithium, sec-butyllithium, 2-naphthyllithium, cyclohexyllithium, and octyllithium, though this enumeration makes no claim to completeness. Furthermore, initiators based on samarium complexes are known for the polymerization of acrylates (Macromolecules, 1995, 28, 7886) and can be used here.

It is also possible, furthermore, to employ difunctional initiators, such as 1,1,4,4-tetraphenyl-1,4-dilithiobutane or 1,1,4,4-tetraphenyl-1,4-dilithioisobutane, for example. Coinitiators can likewise be employed. Suitable coinitiators include lithium halides, alkali metal alkoxides, and alkylaluminum compounds. In one very preferred version the ligands and coinitiators are chosen so that acrylate monomers, such as n-butyl acrylate and 2-ethylhexyl acrylate, for example, can be polymerized directly and do not have to be generated in the polymer by transesterification with the corresponding alcohol.

Methods suitable for preparing poly(meth)acrylate PSAs with a narrow molecular weight distribution also include controlled free-radical polymerization methods. In that case it is preferred to use, for the polymerization, a control reagent of the general formula:

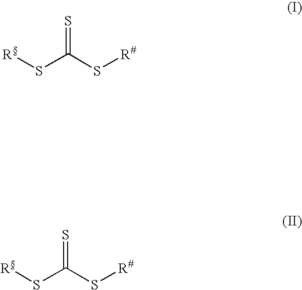

in which R^{§} and R^{#}, chosen independently of one another or identical, are
branched and unbranched C₁ to C₁₈ alkyl radicals; C₃ to C₁₈ alkenyl radicals; C₃ to C₁₈ alkynyl radicals;
C₁ to C₁₈ alkoxy radicals;
C₃ to C₁₈ alkynyl radicals; C₃ to C₁₈ alkenyl radicals; C₁ to C₁₈ alkyl radicals substituted by at least one OH group or a halogen atom or a silyl ether;
C₂-C₁₈ heteroalkyl radicals having at least one oxygen atom and/or one NR* group in the carbon chain, R* being any radical (particularly an organic radical);
C₃-C₁₈ alkynyl radicals, C₃-C₁₈ alkenyl radicals, C₁-C₁₈ alkyl radicals substituted by at least one ester group, amine group, carbonate group, cyano group, isocyano group and/or epoxy group and/or by sulfur;
C₃-C₁₂ cycloalkyl radicals;
C₆-C₁₈ aryl or benzyl radicals;
hydrogen.

Control reagents of type (I) are preferably composed of the following further-restricted compounds:

halogen atoms therein are preferably F, Cl, Br or I, more preferably Cl and Br. Outstandingly suitable alkyl, alkenyl and alkynyl radicals in the various substituents include both linear and branched chains.

Examples of alkyl radicals containing 1 to 18 carbon atoms are methyl, ethyl, propyl, isopropyl, butyl, isobutyl, t-butyl, pentyl, 2-pentyl, hexyl, heptyl, octyl, 2-ethylhexyl, t-octyl, nonyl, decyl, undecyl, tridecyl, tetradecyl, hexadecyl, and octadecyl.

Examples of alkenyl radicals having 3 to 18 carbon atoms are propenyl, 2-butenyl, 3-butenyl, isobutenyl, n-2,4-pentadienyl, 3-methyl-2-butenyl, n-2-octenyl, n-2-dodecenyl, isododecenyl, and oleyl.

Examples of alkynyl having 3 to 18 carbon atoms are propynyl, 2-butynyl, 3-butynyl, n-2-octynyl, and n-2-octadecynyl.

Examples of hydroxy-substituted alkyl radicals are hydroxypropyl, hydroxybutyl, and hydroxyhexyl.

Examples of halogen-substituted alkyl radicals are dichlorobutyl, monobromobutyl, and trichlorohexyl.

An example of a suitable C₂-C₁₈ heteroalkyl radical having at least one oxygen atom in the carbon chain is —CH₂—CH₂—O—CH₂—CH₃.

Examples of C₃-C₁₂ cycloalkyl radicals include cyclopropyl, cyclopentyl, cyclohexyl, and trimethylcyclohexyl.

Examples of C₆-C₁₈ aryl radicals include phenyl, naphthyl, benzyl, 4-tert-butylbenzyl, and other substituted phenyls, such as ethyl, toluene, xylene, mesitylene, isopropylbenzene, dichlorobenzene or bromotoluene.

The above enumerations serve only as examples of the respective groups of compounds, and make no claim to completeness.

Other compounds which can also be used as control reagents include those of the following types:

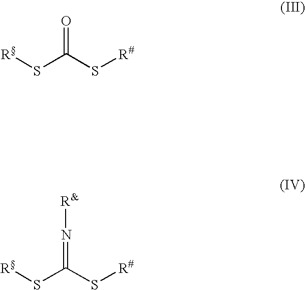

where R^{§} and R^{#} are as defined above and R^{&}, again independently from R^{§} and R^{#}, may be selected from the group recited above for these radicals.

In the case of the conventional ‘RAFT’ process, polymerization is generally carried out only up to low conversions (cf. WO 98/01478 A1) in order to produce very narrow molecular weight distributions. As a result of the low conversions, however, these polymers cannot be used as PSAs and in particular not as hot-melt PSAs, since the high fraction of residual monomers adversely affects the technical adhesive properties; the residual monomers contaminate the solvent recyclate in the concentration operation; and the corresponding self-adhesive tapes would exhibit very high outgassing behavior. In order to circumvent this disadvantage of low conversions, the polymerization in one particularly preferred procedure is initiated two or more times.

As a further controlled free-radical polymerization method it is possible to carry out nitroxide-controlled polymerizations. For free-radical stabilization, in a favorable procedure, use is made of nitroxides of type (Va) or (Vb):

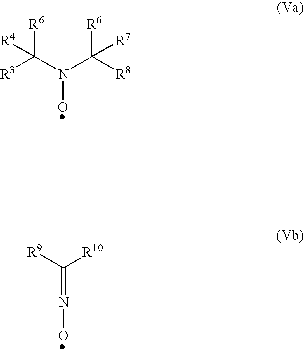

where R³, R⁴, R⁵, R⁶, R⁷, R⁸, R⁹, and R¹⁰ independently of one another denote the following compounds or atoms:
i) halides, such as chlorine, bromine or iodine, for example,
ii) linear, branched, cyclic, and heterocyclic hydrocarbons having 1 to 20 carbon atoms, which may be saturated, unsaturated or aromatic,
iii) esters —COOR¹¹, alkoxides —OR¹² and/or phosphonates —PO(OR¹³)₂, where R¹¹, R¹² or R¹³ stand for radicals from group ii).

Compounds of type (Va) or (Vb) can also be attached to polymer chains of any kind (primarily such that at least one of the abovementioned radicals constitutes a polymer chain of this kind) and may therefore be used for the synthesis of polyacrylate PSAs.

With greater preference, use is made of controlled regulators for the polymerization of compounds of the following types:
2,2,5,5-tetramethyl-1-pyrrolidinyloxyl (PROXYL), 3-carbamoyl-PROXYL, 2,2-dimethyl-4,5-cyclohexyl-PROXYL, 3-oxo-PROXYL, 3-hydroxylimine-PROXYL, 3-aminomethyl-PROXYL, 3-methoxy-PROXYL, 3-t-butyl-PROXYL, 3,4-di-t-butyl-PROXYL
2,2,6,6-tetramethyl-1-piperidinyloxy (TEMPO), 4-benzoyloxy-TEMPO, 4-methoxy-TEMPO, 4-chloro-TEMPO, 4-hydroxy-TEMPO, 4-oxo-TEMPO, 4-amino-TEMPO, 2,2,6,6,-tetraethyl-1-piperidinyloxyl, 2,2,6-trimethyl-6-ethyl-1-piperidinyloxyl
N-tert-butyl 1-phenyl-2-methylpropyl nitroxide
N-tert-butyl 1-(2-naphthyl)-2-methylpropyl nitroxide
N-tert-butyl 1-diethylphosphono-2,2-dimethylpropyl nitroxide
N-tert-butyl 1-dibenzylphosphono-2,2-dimethylpropyl nitroxide
N-(1-phenyl-2-methylpropyl) 1-diethylphosphono-1-methylethyl nitroxide
di-t-butyl nitroxide
diphenyl nitroxide
t-butyl t-amyl nitroxide.

A series of further polymerization methods in accordance with which the PSAs can be prepared by an alternative procedure can be chosen from the prior art:

U.S. Pat. No. 4,581,429 A discloses a controlled-growth free-radical polymerization process which uses as its initiator a compound of the formula R′R″ N—O—Y, in which Y is a free-radical species which is able to polymerize unsaturated monomers. In general, however, the reactions have low conversion rates. A particular problem is the polymerization of acrylates, which takes place only with very low yields and molar masses. WO 98/13392 A1 describes open-chain alkoxyamine compounds which have a symmetrical substitution pattern. EP 735 052 A1 discloses a process for preparing thermoplastic elastomers having narrow molar mass distributions. WO 96/24620 A1 describes a polymerization process in which very specific free-radical compounds, such as phosphorus-containing nitroxides based on imidazolidine, for example, are employed. WO 98/44008 A1 discloses specific nitroxyls based on morpholines, piperazinones, and piperazinediones. DE 199 49 352 A1 describes heterocyclic alkoxyamines as regulators in controlled-growth free-radical polymerizations. Corresponding further developments of the alkoxyamines or of the corresponding free nitroxides improve the efficiency for the preparation of polyacrylates.

As a further controlled polymerization method, atom transfer radical polymerization (ATRP) can be used advantageously to synthesize the polyacrylate PSAs, in which case use is made preferably as initiator of monofunctional or difunctional secondary or tertiary halides and, for abstracting the halide(s), of complexes of Cu, Ni, Fe, Pd, Pt, Ru, Os, Rh, Co, Ir, Ag or Au (EP 0 824 111 A1; EP 826 698 A1; EP 824 110 A1; EP 841 346 A1; EP 850 957 A1). The various possibilities of ATRP are further described in the specifications U.S. Pat. No. 5,945,491 A, U.S. Pat. No. 5,854,364 A, and U.S. Pat. No. 5,789,487 A.

The invention further relates to a process for producing double-sided adhesive tapes particularly for use in LCD manufacture or LCD bonding. The process is notable for the use of a carrier film as already described above, with or without a small fraction of blocking agents.

Films of this kind are difficult or impossible to process by known methods.

Surprisingly it has been found that films with low or zero antiblocking agent content for use in the PSA tapes as described above can be made manageable if the films are coated onto temperature-resistant in-process films, on which the film (PET film, for example) can cool prior to winding. In one version of the process of the invention the temperature-resistant in-process film is wound up as well. Blocking of the film (baking-together of the individual layers) can be avoided in this way without any adverse alteration in the optical properties of the film.

Further surprisingly it has been found that a film with low or zero antiblocking agent content can be further-processed to give the desired PSA tapes and, at the same time, has the properties which are desired for the PSA tapes if the carrier film has been roughened prior to the production of the PSA tape, and in particular if it has been roughened so as to have a roughness of less than 400 nm, preferably of less than 300 nm, and preferably of more than 50 nm (data in the form of RMS roughnesses).

The roughness can be obtained advantageously by means of nanoembossing, as for example by means of a laminating operation (“interleaving”) in which a nonwoven and/or woven fabric is pressed onto the film surface. One advantageous laminating station in this context is composed of at least two rolls between which it is possible to generate the desired pressing pressure. Between the rolls the nonwoven or woven fabric is then laminated onto the film and thereby transfers its surface structure to the film.

In a second version of the process of the invention the surface structure is generated by means of the surface of one of the rolls itself on the surface of the film.

Polishing operations can be used to fine-tune the microroughness of the film surface, by selection of a corresponding polish. In this case it is also possible to have two or more polishing procedures one after another.

To improve the adhesiveness of the subsequent layers to the film, the film can be pretreated, before or after roughening, by etching, by corona or plasma treatment and/or by treatment with a primer.

In one further development the processes described above, particularly the coating onto temperature-resistant in-process films and the roughening, are combined and are both carried out in the operating sequence of the invention.

One very preferred variant process for producing a reflecting layer on the film is that of coating the film on one or both sides by vapor deposition with a metal, aluminum or silver for example. In order to attain particularly outstanding reflecting and light-absorbing properties, it is advantageous to operate by means of the cathodic atomization coating process (i.e., sputtering), the sputtering operation for vapor deposition advantageously being controlled such that the aluminum or silver is applied very evenly. This leads to optimum reflection of the vapor-coated film (avoidance of scattering effects). Furthermore, in one very preferred embodiment, the PET film is vapor-coated with aluminum on one or both sides in one workstep.

In an alternative procedure the reflecting layer applied is a metallic surface coating, advantageously a silver-colored coating. For this purpose, in particular, a binder matrix is blended with silver-colored color pigments. Examples of suitable binder matrices include polyurethanes or polyesters which have a high refractive index and a high transparency. In another procedure the color pigments can be bound into a polyacrylate or polymethacrylate matrix and then cured as a coating material.

The use of the reflecting layer has the effect firstly of reflecting the light in a targeted manner and secondly of reducing the transmittance of the light through the carrier material.

In a further step, the chromophoric layers are applied. Advantageously it is possible to obtain this layer as follows: in a curing binder matrix (preferably a thermosetting system, though radiation-curing system also possible), color pigments are mixed into the coating-material matrix, with black color pigments in particular being selected. Coating materials used can be, for example, polyesters, polyurethanes, polyacrylates or polymethacrylates, in conjunction with the coatings additives that are known to the skilled worker. In one very preferred inventive embodiment the chromophoric particles mixed into the binder matrix are carbon black or graphite particles. With a very high level of additization (>20% by weight), this additization results not only in complete light absorption but also in electrical conductivity, so that the inventive double-sided PSA tapes likewise possess antistatic properties.

For treatment with pressure-sensitive adhesives, in one preferred procedure the pressure-sensitive adhesive is coated from solution onto the carrier film (or, more precisely, onto the layers that have been applied to the carrier film), the said film having been, in particular, prepared in the manner described above. To increase the anchoring of the PSA it is possible optionally to pretreat the metallically reflective layers and/or the chromophoric layers. Thus pretreatment may be carried out, for example, by corona or by plasma, a primer can be applied from the melt or from solution, or etching may take place chemically.

Particularly in the case of a black coating film, however, the corona power ought to be minimized, since otherwise pinholes are burnt into the film. For the coating of the PSA from solution, heat is supplied, in a drying tunnel for example, to remove the solvent and, if appropriate, initiate the crosslinking reaction.

The polymers described above can also be coated, furthermore, as hotmelt systems (i.e., from the melt). For the preparation process it may therefore be necessary to remove the solvent from the PSA. In this case it is possible in principle to use any of the techniques known to the skilled worker. One very preferred technique is that of concentration using a single-screw or twin-screw extruder. The twin-screw extruder can be operated corotatingly or counterrotatingly. The solvent or water is preferably distilled off over two or more vacuum stages. Counterheating is also carried out depending on the distillation temperature of the solvent. The residual solvent fractions amount to preferably <1%, more preferably <0.5%, and very preferably <0.2%. Further processing of the hotmelt takes place from the melt.

For coating as a hotmelt it is possible to employ different coating processes. In one version the PSAs are coated by a roll coating process. Different roll coating processes are described in the “Handbook of Pressure Sensitive Adhesive Technology”, by Donatas Satas (van Nostrand, New York 1989). In another version, coating takes place via a melt die. In a further preferred process, coating is carried out by extrusion. Extrusion coating is performed preferably using an extrusion die. The extrusion dies used may come advantageously from one of the three following categories: T-dies, fishtail dies and coathanger dies. The individual types differ in the design of their flow channels. Through the coating it is also possible for the PSAs to undergo orientation.

In addition it may be necessary for the PSA to be crosslinked. In one preferred version, crosslinking takes place with electronic and/or UV radiation.

UV crosslinking irradiation is carried out with shortwave ultraviolet irradiation in a wavelength range from 200 to 400 nm, depending on the UV photoinitiator used; in particular, irradiation is carried out using high-pressure or medium-pressure mercury lamps at an output of 80 to 240 W/cm. The irradiation intensity is adapted to the respective quantum yield of the UV photoinitiator and the degree of crosslinking that is to be set.

Furthermore, in one embodiment, it is possible to crosslink the PSAs using electron beams. Typical irradiation equipment which can be employed includes linear cathode systems, scanner systems, and segmented cathode systems, where electron beam accelerators are employed. A detailed description of the state of the art and the most important process parameters can be found in Skelhorne, Electron Beam Processing, in Chemistry and Technology of UV and EB formulation for Coatings, Inks and Paints, Vol. 1, 1991, SITA, London. The typical acceleration voltages are situated in the range between 50 kV and 500 kV, preferably between 80 kV and 300 kV. The scatter doses employed range between 5 to 150 kGy, in particular between 20 and 100 kGy.

It is also possible to employ both crosslinking processes, or other processes allowing high-energy irradiation.

The invention further provides for the use of the inventive double-sided pressure-sensitive adhesive tapes for adhesive bonding or production of optical liquid-crystal displays (LCDs), their use for the adhesive bonding of LCD glasses, and liquid-crystal displays having an inventive pressure-sensitive adhesive tape in their construction. For use as pressure-sensitive adhesive tape it is possible for the double-sided pressure-sensitive adhesive tapes to have been lined with one or two release films or release papers. In one preferred embodiment use is made of siliconized or fluorinated films or papers, such as glassine, HDPE or LDPE coated papers, for example, which have in turn been given a release coat based on silicones or fluorinated polymers.

### EXAMPLES

The invention is described below, without wishing any unnecessary restriction to result from the choice of the examples.

The following test methods were employed.

### Test Methods

### A. Transmittance

The transmittance was measured in the wavelength range from 190 to 900 nm using a Uvikon 923 from Biotek Kontron. The absolute transmittance is reported in % as the value at 550 nm.

### B. Pinholes

A very strong light source of commercially customary type (e.g., Liesegangtrainer 400 KC type 649 overhead projector, 36 V halogen lamp, 400 W) is given completely lightproof masking. This mask contains in its center a circular aperture having a diameter of 5 cm. The double-sided LCD adhesive tape is placed atop said circular aperture. In a completely darkened environment, the number of pinholes is then counted electronically or visually. When the light source is switched on, these pinholes are visible as translucent dots.

### C. Reflection

The reflection test is carried out in accordance with DIN standard 5063 part 3. The instrument used was a type LMT Ulbrecht sphere. The reflectance is reported as the sum of directed and scattered light fractions in %.

### Polymer 1

A 200 l reactor conventional for free-radical polymerizations was charged with 2400 g of acrylic acid, 64 kg of 2-ethylhexyl acrylate, 6.4 kg of N-isopropylacrylamide and 53.3 kg of acetone/isopropanol (95:5). After nitrogen gas had been passed through the reactor for 45 minutes with stirring, the reactor was heated to 58° C. and 40 g of 2,2′-azoisobutyronitrile (AIBN) were added. Subsequently the external heating bath was heated to 75° C. and the reaction was carried out constantly at this external temperature. After a reaction time of 1 h a further 40 g of AIBN were added. After 5 h and 10 h, dilution was carried out with 15 kg each time of acetone/isopropanol (95:5). After 6 h and 8 h, 100 g each time of dicyclohexyl peroxydicarbonate (Perkadox 16®, Akzo Nobel) in solution in each case in 800 g of acetone were added. The reaction was terminated after a reaction time of 24 h, and the reaction mixture cooled to room temperature.

### Crosslinking

The PSAs are coated from solution onto a siliconized release paper (PE coated release paper from Loparex), dried in a drying cabinet at 100° C. for 10 minutes, and then crosslinked with a dose of 25 kGy at an acceleration voltage of 200 kV. The coatweight was in each case 50 g/m².

### Film (Al Vapor Coating):

A polyethylene terephthalate copolymer was mixed with 20% by weight of titanium dioxide (average diameter 0.25 μm) in a compounder at 180° C. for 2 h and the mixture was dried under reduced pressure. The film material was then extruded in a single-screw extruder through a slot die (T-shape, 300 μm die gap) at 280° C. The film is applied to a mirrored chill roll. It is subsequently oriented 3.5 times in the machine direction by heating at 90 to 95° C. The film is subsequently run into a tensioning device. There, using clamps, it is oriented 4-fold in the cross direction at temperatures between 100° C. and 110° C. Subsequently it is reheated at 210° C. for 10 s. Before winding, a 13 g/m² paper web is introduced in order to prevent blocking. In this condition, the film could be wound and stored. The white PET film possesses a total thickness of 38 μm.

After unwinding and the removal of the web, this PET film was vapor coated on one side with aluminum until a complete layer of aluminum is applied to one side. The film was vapor-coated in a width of 300 mm by the sputtering method. In this method, positively charged, ionized argon gas is passed into a high-vacuum chamber. The charged ions then impinge on a negatively charged Al plate and, at the molecular level, detach particles of aluminum, which then deposit on the polyester film which is passed over the plate.

### Reference Film (Al Vapor Coating):

A 38 μm PET film, extruded with white pigments as filler, from Toray (Lumirror™ 38E20) was vapor coated on one side with aluminum until a complete layer of aluminum is applied to one side. The film was vapor-coated in a width of 300 mm by the sputtering method. In this method, positively charged, ionized argon gas is passed into a high-vacuum chamber. The charged ions then impinge on a negatively charged Al plate and, at the molecular level, detach particles of aluminum, which then deposit on the polyester film which is passed over the plate.

### Preparation of the Black Ink:

The black ink was prepared from 4 parts of curative CVL No. 10 (from Dainippon Ink and Chemicals, Inc.) and 35 parts of Daireducer™ V No. 20 (from Dainippon Ink and Chemicals, Inc.) and also 100 parts of Panacea™ CVL-SPR805 ink (from Dainippon Ink and Chemicals, Inc., a vinyl chloride/vinyl acetate based ink).

The disclosure content of US 2004/0028895 with regard to the preparation of “black ink A” and to the properties cited in relation to said ink is explicitly included in the disclosure content of this specification.

### Preparation of the White Ink:

The white ink was prepared from 2 parts of curative CVL No. 10 (from Dainippon Ink and Chemicals, Inc.) and 35 parts of Daireducer™ V No. 20 (from Dainippon Ink and Chemicals, Inc.) and also 100 parts of Panacea™ CVL-SP709 ink (from Dainippon Ink and Chemicals, Inc., a vinyl chloride/vinyl acetate based ink).

The disclosure content of US 2004/0028895 with regard to the preparation of “white ink W” and to the properties cited in relation to said ink is explicitly included in the disclosure content of this specification.

### Film 1 (Black/White):

The black ink is applied over the Al-coated side of the film (for basis see film Al vapor coating) and dried at 45° C. for 48 hours. The side coated with black coating material is completely and uniformly black. The coatweight is approximately 2 g/m².

### Film 2 (Black/White):

The white ink is applied over the Al-coated side of the film (for basis see film Al vapor coating) and dried at 45° C. for 48 hours. The coatweight is 2 g/m². Then the same side is coated again with the black ink. Drying is carried out again at 45° C. for 48 hours. The side coated doubly with coating material is completely and uniformly black. The coatweight of both inks is 4 g/m².

### Reference Film 1 (Black/White):

The black ink is applied over the Al-coated side of the film (for basis see reference film Al vapor coating) and dried at 45° C. for 48 hours. The side coated with black coating material is completely and uniformly black. The coatweight is approximately 2 g/m².

### Reference Film 2 (Black/White):

The white ink is applied over the Al-coated side of the film (for basis see reference film Al vapor coating) and dried at 45° C. for 48 hours. The coatweight is 2 g/m². Then the same side is coated again with the black ink. Drying is carried out again at 45° C. for 48 hours. The side coated doubly with coating material is completely and uniformly black. The coatweight of both inks is 4 g/m².

### Example 1

Film 1 is coated by lamination with polymer 1 on both sides at 50 g/m².

### Example 2

Film 2 is coated by lamination with polymer 1 on both sides at 50 g/m².

### Reference Example 1

Reference film 1 is coated by lamination with polymer 1 on both sides at 50 g/m².

### Reference Example 2

Reference film 2 is coated by lamination with polymer 1 on both sides at 50 g/m².

### Results

Examples 1 and 2 were tested together with reference examples 1 and 2 in accordance with test methods A, B, and C. The results are set out in Table 1.

TABLE 1

| | Transmittance | Pinholes | Reflectance (total) |
|---|---|---|---|
| Example | (test A) | (test B) | (test C) |
| 1 | <0.1% | 0 | 83.2% |
| 2 | <0.1% | 0 | 83.6% |
| Reference 1 | <0.1% | 22 | 79.8% |
| Reference 2 | <0.1% | 24 | 80.1% |

From the results in Table 1 it is apparent that examples 1 to 2 are significantly superior to reference examples 1 and 2 in respect of optical defects (absence of pinholes) and total reflectance rate. There is therefore a significant increase in the light yield in the case of LCD application.

Inventively and surprisingly, the PSA tapes of the invention do not exhibit blocking at any stage of their production. This is true for the single-sidedly or double-sidedly metallized film too, and continues to be true even after coating. Such advantageous characteristics could not have been expected by the skilled worker.

It was surprising to the skilled worker that the pale, in particular white color pigments and particles did not cause the problems known from antiblocking agents, and in particular produced no pinholes.

1. A pressure-sensitive adhesive tape comprising a carrier film having a top side and a bottom side and a pressure-sensitive adhesive layer applied directly or indirectly on both sides, wherein the carrier film has an antiblocking agent content of less than 4000 ppm, the carrier film is pale colored, there is at least one light-absorbing chromophoric layer at least between the bottom side of the carrier film and the pressure-sensitive adhesive layer located on that side and the pressure-sensitive adhesive tape exhibits light-reflecting properties on a top side and light-absorbing properties on a bottom side.

2. The pressure-sensitive adhesive tape of claim 1, wherein the pale coloring of the carrier layer is achieved by the presence of white pigments.

3. The pressure-sensitive adhesive tape of claim 1, wherein the carrier film has an antiblocking agent content of less than 1000 ppm.

4. The pressure-sensitive adhesive tape of claim 1, wherein at least one of the sides of the carrier film has a roughness of less than 400 nm.

5. The pressure-sensitive adhesive tape of claim 1, wherein the carrier film has a thickness of between 250 μm and 4 μm.

6. The pressure-sensitive adhesive tape of claim 1, wherein the carrier film is provided on its bottom side with a metallically reflecting coating.

7. A process for producing a pressure-sensitive adhesive tape of claim 1, comprising roughening a surface of the carrier film on at least one of its sides and then combining with other layers of the pressure-sensitive adhesive tape to produce the pressure-sensitive adhesive tape.

8. The process of claim 7, wherein the surface of the carrier film is roughened by pressured application of a nonwoven and/or woven fabric and/or by treatment with surface-structured rolls and is refined if appropriate by polishing.

9. The process of claim 8, wherein the carrier film is pretreated, before or after roughening by etching, by corona or plasma treatment and/or by treatment with a primer.

10. The process of claim 7, wherein the metallically reflecting coating is obtained by sputtering (cathodic atomization coating).

11. A method of bonding components of an optical liquid-crystal display comprising bonding said components with a pressure-sensitive adhesive tape of claim 1.

12. The method of claim 11, wherein said components are components of an LCD glass.

13. A liquid-crystal display (LCD) comprising a pressure-sensitive adhesive tape of claim 1.
